(19) United States
(12) Patent Application Publication
(10) Pub. No.: US 2017/0107615 A1
(43) Pub. Date: Apr. 20, 2017

(54) GAS-PHASE DEPOSITION PROCESS

(71) Applicant: Altatech Semiconductor, Montbonnot-Saint-Martin (FR)

(72) Inventor: Julien Vitiello, Grenoble (FR)

(21) Appl. No.: 15/127,218

(22) PCT Filed: Mar. 19, 2015
(86) PCT No.: PCT/EP2015/055821

§ 371 Date: Sep. 19, 2016

(30) Foreign Application Priority Data
Mar. 21, 2014 (FR) 1452385

(51) Int. Cl. C23C 16/455

(52) U.S. Cl. CPC C23C 16/45525; C23C 16/45574

(57) ABSTRACT

The disclosure relates to a layer-deposition process that includes: injecting a first reagent in gaseous phase into the deposition chamber via a first injection path, and injecting a second gas-phase reagent into the deposition chamber via a second injection path, the second injection path being separate from the first injection path. The pressure in the deposition chamber is greater than a predetermined value for the entire duration of the process. The process is characterized in that the first reagent is fed into the deposition chamber according to a first pulse sequence, and the second reagent is fed into the chamber according to a second pulse sequence. The first pulse sequence and the second pulse sequence are out of phase with one another.

### CROSS-REFERENCE TO RELATED APPLICATIONS

This application is a national phase entry under 35 U.S.C. §371 of International Patent Application PCT/EP2015/055821, filed Mar. 19, 2015, designating the United States of America and published as International Patent Publication WO 2015/140261 A1 on Sep. 24, 2015, which claims the benefit under Article 8 of the Patent Cooperation Treaty to French Patent Application Serial No. 1452385, filed Mar. 21, 2014.

### TECHNICAL FIELD

The present disclosure relates to a method for gas phase deposition of a layer on the surface of a substrate placed in a deposition chamber.

### BACKGROUND

A method for gas phase deposition of a layer 1 by reaction between two reagents on the surface of a substrate 2 placed in a deposition chamber 3, illustrated in FIG. 1, and known from the state of the art, comprises the following steps:
a first reagent is injected in a gas phase into the deposition chamber 3 through a first injection route 4;
a second reagent is injected in a gas phase into the deposition chamber 3 through a second injection route 5, the second injection route 5 being different from the first injection route 4;
the pressure in the deposition chamber 3 is maintained constant during the whole duration of the method.

However, this method commonly called “Chemical Vapor Deposition” and designated under the acronym of CVD, is not satisfactory.

Indeed, when the first reagent and the second reagent have strong reactivity, they react with each other before having arrived at the surface of the substrate 2 placed in the deposition chamber 3. These reactions, described as parasitic reactions, generate a strong deficiency of the layers formed by CVD, and especially alter their properties, notably the electrical, optical and crystalline characteristics.

Moreover, the capability of the CVD technique of covering in a conforming way structures present on the surface of the substrate 2 is degraded gradually as the aspect ratio of the structures increases. By “structure” is meant patterns or devices present on the surface of the substrate 2. The aspect ratio is determined by the ratio between the width of a structure and its height (or its depth if this is a recessed structure). By “conforming” is meant the fact that the thickness of the layer deposited by CVD is constant in any point of the surface of the structures exposed to the reactive gases. Thus, it is commonly recognized that the conformity of a layer formed by the CVD technique is satisfactory when the aspect ratio of structures present on the surface of the substrate 2 is less than 1:10. On the other hand, for greater aspect ratios, the covering of the structures is not uniform and/or is incomplete as illustrated in FIG. 2.

This is notably the case in the manufacturing of electromechanical microsystems (MEMS), for which the aspect ratios may be very high, for example, the filling of deep trenches (depth greater than 20 μm) and with a very narrow aperture (of less than 2 μm).

A goal of the invention is, therefore, to propose a method for forming a layer involving highly reactive species, with the layer having very low deficiency.

Another goal of this disclosure is to propose a method for forming a layer having better conformity than conventional CVD.

### BRIEF SUMMARY

This disclosure aims at finding a remedy, either totally or partially, to the aforementioned drawbacks, and relates to a method for gas phase deposition of a layer by reaction between two reagents on the surface of a substrate placed in a deposition chamber, the method comprising:
the injection of a first reagent in a gas phase into the deposition chamber through a first injection route;
the injection of a second reagent in a gas phase into the deposition chamber through a second injection route, the second injection route being distinct from the first injection route;
wherein the pressure in the deposition chamber is greater than 500 mTorr during the whole duration of the method and in that the first reagent is introduced into the deposition chamber according to a first sequence of pulses, the second reagent is introduced into the chamber according to a second sequence of pulses, the first sequence of pulses and the second sequence of pulses being phase-shifted.

By “sequence of pulses” is meant at least one pulse per sequence. This method is called pulsed CVD.

Thus, it is possible to retain the advantage of a deposition rate of a layer on the surface of a substrate, comparable with the chemical vapor deposition technique (CVD).

Moreover, the conformity of the deposition of the layer is greatly improved as compared with the chemical vapor deposition technique.

Further, this method promotes a reaction between the first reagent and the second reagent on the surface of the substrate, thereby limiting parasitic reactions, and the formation of contamination, which may degrade the properties of the layer formed on the surface of the substrate.

According to an embodiment, the pressure in the deposition chamber is greater than 1 Torr.

According to an embodiment, the first reagent and the second reagent react according to a reaction time less than the travel time of a system for injecting reagents to the surface of the substrate of the first reagent and of the second reagent, the system for injecting reagents comprising the first injection route and the second injection route.

According to an embodiment, the first sequence of pulses is periodic and has a first period.

According to an embodiment, the second sequence of pulses is periodic and has a second period.

According to an embodiment, the first period and the second period are equal.

According to an embodiment, the overlapping between the pulses of the first sequence of pulses and the second sequence of pulses is zero.

According to an embodiment, the time interval between two successive pulses of the first sequence of pulses is greater than the duration of the pulses of the first sequence of pulses.

According to an embodiment, the interval between two successive pulses of the second sequence of pulses is greater than the duration of the pulses of the second sequence of pulses.

According to an advantageous embodiment, the first injection route comprises a first plurality of channels through which the first reagent is injected into the deposition chamber and the second injection route comprises a second plurality of channels through which the second reagent is injected into the deposition chamber, the channels opening into the deposition chamber facing the surface of the substrate.

### BRIEF DESCRIPTION OF THE DRAWINGS

Other features and advantages will become apparent in the description that follows of embodiments of a method for gas phase deposition of a layer on the surface of a substrate according to the disclosure, given as non-limiting examples, with reference to the appended drawings, wherein:

FIG. 1 shows a block diagram of a deposition chamber used by a technique of the prior art;

FIG. 2 shows the conformity of a layer deposited by a technique of the prior art;

FIG. 3 is a block diagram of a deposition chamber used for this disclosure;

FIG. 4 is a block diagram of sequences of pulses according to an embodiment of the disclosure; and

FIG. 5 is a block diagram of sequences of pulses according to an embodiment of the disclosure.

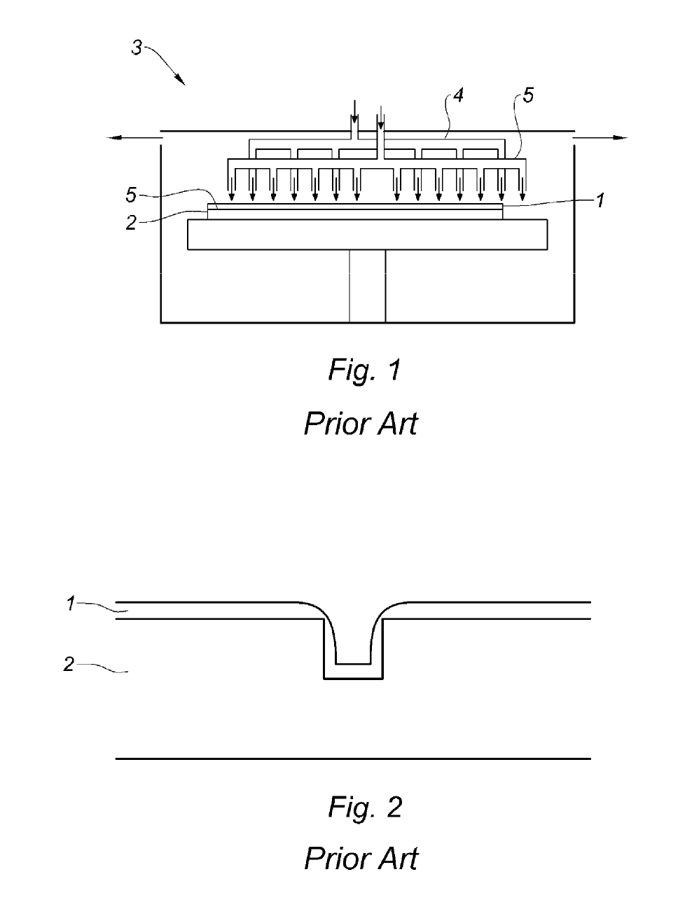

### DETAILED DESCRIPTION

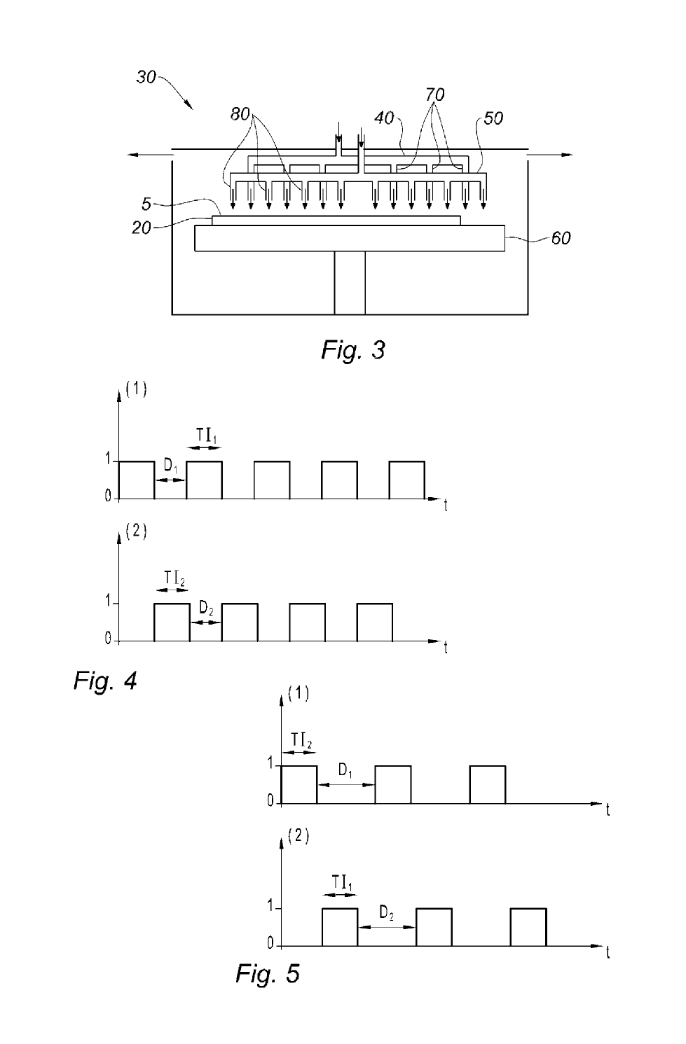

For the different embodiments, the same references will be used for identical elements or ensuring the same function, for sake of simplifying the description. The device allowing the carrying out of the invention is illustrated in FIG. 3.

The substrate 20 is then placed on a substrate holder 60 in the deposition chamber 30, and comprises a free surface S on which the layer 10 may be formed by reaction of the first reagent with the second reagent on the surface S.

The free surface S faces a system for injecting the reagents. The system for injecting reagents comprises a first injection route 40 and a second injection route 50 distinct from the first injection route 40. A system for injecting reagents that may be used in this disclosure is described in French Patent Application Serial No. FR 2 930 561.

The first injection route 40 comprises a first plurality of channels 70 opening out from the system for injecting the reagents (FIG. 3).

The second injection route 50 comprises a second plurality of channels 80 opening out from the system for injecting reagents.

The open output ends of the channels of the first plurality of channels 70 and of the second plurality of channels 80 face the free surface S of the substrate 20.

The channels of the first plurality of channels 70 and of the second plurality of channels 80 may be regularly distributed in the system for injecting the reagents. The regular distribution of the channels of the first plurality of channels 70 and of the second plurality of channels 80 gives the possibility of improving the uniformity of the layer 10 formed on the free surface S of the substrate 20.

This regular distribution is obtained by maintaining a predetermined distance between the channels of the first plurality of channels 70 as well as between the channels of the second plurality of channels 80 resulting in a pattern of an equidistant distribution. This distribution may be of the triangular type for both types of channels in order to optimize the use of the space in the plane facing the free surface S.

The system for injecting the reagents comprises a heating system (not shown) allowing injection of the reagents along the first injection route 40 and the second injection route 50 in the gas state and at a temperature T1.

The substrate holder 60 also comprises a heating system (not shown) intended for heating the substrate 20.

A gas discharge system is placed in the deposition chamber 30 for discharging the reagents that have not reacted on the free surface S of the substrate 20.

The gas phase deposition method then comprises the injection of a first reagent in a gas phase through the first injection route 40, and the injection of a second reagent in a gas phase through the second injection route 50.

The disclosure is of particular interest for a gas phase deposition method of the direct liquid injection (DLI) type. This method comprises bringing the precursor, which is in the liquid state at room temperature, to the liquid state as far as a vaporization area. This vaporization area is very well controlled in temperature in order to allow efficient vaporization without degrading the precursor. The output of the vaporization area is in contact with a carrier gas in order to be able to bring the vaporized precursor as far as the deposition area. The advantages of this approach as compared with traditional technologies for vaporizing a liquid precursor, which are bubbling and evaporation, are, on one side, to allow independent control of the three key vaporization parameters, which are the temperature, the precursor flow rate and the carrier gas flow rate, and, on the other side, to avoid the influence of the working pressure in the chamber on the capability of vaporizing a precursor, while this influence is direct for evaporation or bubbling. The latter point is of particular interest for an injection of a plurality of reagents or precursors with a phase shift between the different sequences of pulses, a same chamber pressure being able to be used for different types of precursors or reagents and better injection control may be achieved.

The travel time of the first reagent and of the second reagent between the system for injecting the reagents and the free surface S of the substrate 20 is defined as being the time taken by the first and the second reagent for covering the distance between the system for injecting the reagents and the free surface S of the substrate 20.

The disclosure seeks to place the substrate 20 under conditions such that the injection of the first reagent and of the second reagent will not generate parasitic reactions that may contaminate and degrade the electric, crystalline and optical properties of the thereby formed layer 10.

To do this, the disclosure then proposes an injection mode of the first reagent and the second reagent adapted so that the reaction between both reagents essentially takes place on the free surface S of the substrate 20.

According to an embodiment, a first reagent is injected into the deposition chamber 30 through the first injection route 40 according to a first sequence of pulses and at a temperature T1.

A second reagent is injected into the deposition chamber 30 through the second injection route 50 according to a second sequence of pulses and at a temperature T1.

The first reagent and the second reagent may react with each other.

The reaction kinetics between the first reagent and the second reagent increase with temperature.

Advantageously, the system for heating the substrate holder 60 heats the substrate 20 to a temperature T2, which is greater than the temperature T1. Since the reaction rate between the first reagent and the second reagent increases with temperature, the reaction rate will be greater on the free surface of the substrate 20.

The first sequence of pulses and the second sequence of pulses are phase shifted, i.e., during the deposition process, there exists successive instants during which only the first reagent is injected into the deposition chamber and instants during which only the second reagent is injected into the reaction chamber. Optionally, there may exist instants during which both reagents are injected simultaneously and/or instants during which no reagent is injected.

Moreover, the pressure in the deposition chamber 30 is greater than a predetermined value during the whole duration of the method unlike the atomic layer deposition techniques (ALD).

Indeed, deposition by ALD comprises the injection of a single reagent at a time, and requires a complete purging of the chamber before the other reagent is injected. In the case of this disclosure, it is possible to do without complex pumping systems and purging steps slowing down the deposition rates of layers on the substrates.

As an example, the pressure in the deposition chamber 30 is greater than 500 mTorr, preferably greater than 1 Torr.

Separate management of the first reagent and of the second reagent and according to a phase-shifted injection method of the first and second reagents will promote the reaction of the latter on the free surface S of the substrate 20 rather than in the space between the free surface S of the substrate 20 and the injection system.

Indeed, when the first reagent is injected during the duration of a pulse in the deposition chamber 30 through the first injection route 40, the first reagent is partly adsorbed on the free surface S of the substrate 20 and partly pumped by the gas discharge system. Thus, the first reagent is then present in a smaller amount in the space between the free surface S of the substrate 20 and the injection system.

The second reagent is injected into the deposition chamber 30 according to phase-shifted pulses with respect to the first reagent.

Thus, the reaction rate between the first reagent and the second reagent in the space between the free surface S of the substrate 20 and the gas injection system is, therefore, reduced as compared with an injection sequence of the first and second reagents according to a continuous flow. The first reagent and the second reagent then preferentially react on the free surface S of the substrate 20.

This injection mode of the first reagent and the second reagent is of particular interest when the first reagent and the second reagent may react during a reaction time, which is less than the travel time defined above.

The method according to the disclosure thus gives the possibility of reducing the rate of parasitic reactions generating particles as compared with a chemical vapor deposition method known from the prior art.

FIG. 4 gives an example of a first sequence of pulses ((1) in FIG. 4), and of a second sequence of pulses ((2) in FIG. 4). The first sequence of pulses and the second sequence of pulses are illustrated as square waves versus time t, but the present disclosure is not limited to this embodiment. With reference to FIG. 3, a reagent is injected into the deposition chamber 30 when the square wave is equal to 1, the square wave then corresponds to one pulse.

The duration of a pulse then corresponds to the time during which a reagent is injected into the deposition chamber 30.

The time separating two successive pulses of a sequence of pulses is designated as interval, and corresponds to a time period during which the reagent is not injected into the deposition chamber 30.

Thus, for the first sequence of pulses, we define the following terms:
the duration of a pulse of the first sequence of pulses: TI1
an interval between two successive pulses of the first sequence of pulses: D1.

Equivalently, for the second sequence of pulses, we define the following terms:
the duration of a pulse of the second sequence of pulses: TI2
an interval between two successive pulses of the second sequence of pulses: D2.

It is possible to adjust the phase shift between the first sequence of pulses and the second sequence of pulses depending on the reactivity of the first reagent and of the second reagent.

Indeed, the greater the reactivity between the first reagent and the second reagent, the greater the phase shift will have to be. The overlapping between the pulses of the first sequence of pulses and the pulses of the second sequence of pulses (i.e., the instants during which both reagents are injected simultaneously) will, in the case of strong reactivity between the first reagent and the second reagent then have to be minimized, and preferably be zero.

Moreover, it may be advantageous to consider an interval D1 greater than TI1, and an interval D2 greater than TI2. In the case of strong reactivity between the first reagent and the second reagent, this will have the effect of promoting the reaction between the first reagent and the second reagent on the free surface S of the substrate 20.

Thus, according to both aforementioned conditions, time is left for each type of reagent to be optimally adsorbed on the free surface S of the substrate 20 before the arrival of the other reagent. This configuration of the method then gives the possibility of minimizing the parasitic reactions in the space comprised between the free surface S of the substrate 20 and the gas injection system.

The first sequence of pulses may be periodic and have a first period.

The second sequence of pulses may also be periodic and have a second period.

The first period and the second period may be equal.

The duration TI1 of a pulse of the first sequence of pulses may be between 0.02 second and 5 seconds.

The interval D1 between two pulses of the first sequence of pulses may be between 0.5 second and 10 seconds.

The duration TI2 of a pulse of the second sequence of pulses may be between 0.02 second and 5 seconds.

The interval D2 between two pulses of the second sequence of pulses may be between 0.5 second and 10 seconds.

The pulses of the first sequence of pulses may have a duration TI1 less than the interval D1 separating two successive pulses of the first sequence of pulses (FIG. 5 (1)).

The pulses of the second sequence of pulses may have a duration TI2 less than the interval D2 separating two successive pulses of the second sequence of pulses (FIG. 4 (2)).

Thus, separate management of the injection of the first reagent and of the second reagent, when the latter are highly reactive, gives the possibility of opening the route for deposition of layers comprising the first and second reagents via an alternative deposition technique to ALD. Advantageously, the deposition technique according to the disclosure gives the possibility of obtaining such layers with growth rates comparable with continuous chemical vapor deposition techniques.

As an example, the deposition of a layer 10 of a conductive transparent oxide of the zinc oxide type AZO (Al-doped ZnO) is disclosed.

The precursors of choice in terms of cost and quality are usually diethyl zinc for providing Zn and trimethyl aluminum for providing Al. Unfortunately, these precursors are sensitive to any oxygen molecule, from a concentration of 5 ppm, while generating a white powder that blocks the growth of the film and generates a deficiency on the substrate 20, making the final devices inoperative. This maximum sensitivity forces the use of a not very reactive oxygen source, either with oxygen gas, or with steam with standard techniques of the CVD or ALD type.

In the first case, it is necessary to add plasma-assistance in order to allow the growth of the layer on the substrate 20 but this is to the detriment of the crystalline qualities of the layer. In the second case, unavoidable trapping of hydrogen components in the layer degrades the crystalline quality of the layer.

The alternative to both of these sources is the use of an oxygen source containing ozone. Being much more reactive than oxygen, this gives the possibility of doing without the plasma assistance and, therefore, without these drawbacks. Further, no hydrogen components are included in the layer with respect to steam, which gives the possibility of obtaining a qualitative growth of the layer (see performance table below). On the other hand, its high reactivity does not allow it to be used in a standard CVD method since it reacts with the precursor before the substrate 20 and is transformed into powder instead of growing on the substrate 20. By using the ozone in the ALD method, it is possible to sequence the phases when the precursor and the ozone are in contact on the substrate 20 for avoiding these problems, but it induces two difficulties as compared with a continuous CVD method. This very slow growth, which gives the possibility of attaining significant conformities on patterns with a high aspect ratio, makes the trapping of aluminum atoms used as a dopant for producing the conductive portion of the layer difficult. The resistivity properties of the layer are increased by this, and the transparency of the layer (notably via the extinction coefficient) is reduced. Further, the slow growth of the zinc oxide layer will promote grains of significant size for thick layers (typically greater than 20 nm) and, therefore, limit both properties specified above, which are the conductivity and the transparency to white light. Conversely, the pulsed CVD method will not only give the possibility of doing without the problems posed by the CVD and ALD method for growing with ozone but also of pushing even further the performances of the deposited film, notably in terms of conductivity and transparency (see table below). This is obtained by the unique combination of the handling of the reactive species in a pulse method, and those separately according to their affinities as far as the surface of the substrate 20. The pulse times are typically from 50 to 200 ms, a time shift between the pulses comprised between 0 and 500 ms, without any purging gas. The working pressure is comprised between 1.5 Torr and 3 Torr, preferably between 1.5 Torr and 2.3 Torr. The gas flows are comprised between 500 sccm and 3,000 sccm, preferably between 500 sccm and 1,500 sccm.

| Specification | AZO 400° C. | AZO 400° C. | Al₂O₃ 400° C. |
|---|---|---|---|
| Deposition rate | 1.24 | 1.2 | 0.33 |
| (nm/s) | | | |
| Resistivity | 2.13 | 2.64 | NA |
| (mOhm · cm) | | | |
| Uniformity of the | 8.9 | 4.5 | NA |
| resistivity (1 s) | | | |
| Uniformity of the | 1.5% | 1.5% | <2.5% |
| thickness (1 s) | | | |
| Transmittance | >92% | >92% | |

1. A method for gas phase deposition of a layer by reaction between two reagents on the surface of a substrate placed in a deposition chamber, the method comprising:
injecting a first reagent in a gas phase into the deposition chamber through a first injection route;
injecting a second reagent in a gas phase into the deposition chamber through a second injection route, the second injection route being distinct from the first injection route;
wherein a pressure in the deposition chamber is greater than 500 mTorr during the whole duration of the method and the first reagent is introduced into the deposition chamber according to a first sequence of pulses, the second reagent is introduced into the deposition chamber according to a second sequence of pulses, the first sequence of pulses and the second sequence of pulses being phase-shifted.

2. The method according to claim 1, wherein the pressure in the deposition chamber is greater than 1 Torr.

3. The method according to claim 1, wherein the first reagent and the second reagent react together for a reaction time less than the travel time of the first reagent and of the second reagent between a system for injecting the first and second reagents and the surface of the substrate, the system for injecting the first and second reagents comprising the first injection route and the second injection route.

4. The method according to claim 1, wherein the first sequence of pulses is periodic and has a first period.

5. The method according to claim 1, wherein the second sequence of pulses is periodic and has a second period.

6. The method according to claim 1, wherein the first sequence of pulses is periodic and has a first period and the second sequence of pulses is periodic and has a second period, and the first period and the second period are equal.

7. The method according to claim 1, wherein an overlapping between the pulses of the first sequence of pulses and the pulses of the second sequence of pulses is zero.

8. The method according to claim 1, wherein an interval between two successive pulses of the first sequence of pulses is greater than a duration of the pulses of the first sequence of pulses.

9. The method according to claim 1, wherein an interval between two successive pulses of the second sequence of pulses is greater than a duration of the pulses of the second sequence of pulses.

10. The method according to claim 1, wherein the pressure in the deposition chamber is between 1.5 Torr and 3 Torr.

11. The method according to claim 1, wherein a duration of a pulse of the first sequence of pulses is between 0.02 second and 5 seconds.

12. The method according to claim 1, wherein an interval between two pulses of the first sequence of pulses is between 0.5 second and 10 seconds.

13. The method according to claim 1, wherein a duration of a pulse of the second sequence of pulses is between 0.02 second and 5 seconds.

14. The method according to claim 1, wherein an interval between two pulses of the second sequence of pulses is between 0.5 second and 10 seconds.

15. The method according to claim 1, wherein a duration of the pulses of the first sequence of pulses and of the second sequence of pulses is between 50 ms and 200 ms.

16. The method according to claim 1, wherein a shift between the pulses of the first sequence of pulses and the pulses of the second sequence of pulses is comprised between 0 and 500 ms.

17. The method according to claim 1, comprising the deposition of a layer of a conductive transparent oxide of Al-doped ZnO type.
